(19) United States
(12) Patent Application Publication
(10) Pub. No.: US 2024/0349424 A1
(43) Pub. Date: Oct. 17, 2024

(54) METHOD AND SYSTEM FOR PROVIDING ILLUMINATING OBJECTS WITHIN SUBSTRATE

(71) Applicants: John Simonetti, Lynnfield, MA (US); Steve Sweeney, Beverly, MA (US)

(72) Inventors: John Simonetti, Lynnfield, MA (US); Steve Sweeney, Beverly, MA (US)

(21) Appl. No.: 18/437,391

(22) Filed: Feb. 9, 2024

Related U.S. Application Data
(60) Provisional application No. 63/485,500, filed on Feb. 16, 2023.

(51) Int. Cl. H05K 1/09; H05K 1/05; H05K 1/11

(52) U.S. Cl. CPC H05K 1/092; H05K 1/056; H05K 1/118; H05K 2201/10106; H05K 2201/10977

(57) ABSTRACT

Provided is a circuit system including a clear ink formed of silver and carbon nanotubes and an opaque ink trace including silver paste ink. The circuit system is embedded in a polymer such as polyethylene terephthalate (PET). The circuit system can include elements such as light emitting diodes (LEDs) and one or more capacitive buttons.

### CROSS-REFERENCE TO RELATED APPLICATIONS

This application claims the benefit of U.S. Provisional Application No. 63/485,500, entitled METHOD AND SYSTEM FOR PROVIDING ILLUMINATING OBJECTS WITHIN SUBSTRATE, filed Feb. 16, 2023, which is fully incorporated herein by reference.

### I. BACKGROUND

The present disclosure is directed to the field of flexible circuits which can be incorporated within a substrate. The present disclosure is particularly directed to the field of circuits which can be formed within a substrate for activating and/or interacting with electronic components embedded in the substrate.

### II. SUMMARY OF THE INVENTION

The present disclosure is directed to a circuit that uses translucent conductive ink to produce customizable and controllable arrangements on a substrate material. In accordance with one aspect of this disclosure, provided is a circuit system including a translucent conductive ink comprised of silver nanowire and/or carbon nanotubes, in combination with opaque conductive silver paste ink and graphic ink. The circuit system is applied onto a polymer film such as polyethylene terephthalate (PET) or polycarbonate (PC). The circuit system can include electronics components such as light emitting diodes (LEDs), microprocessors and other components. It can also incorporate one or more capacitive sensor buttons.

The translucent circuit can be used for various applications. The translucent circuit can be utilized for capacitance switches. The capacitance switch can be actuated by a human finger. The capacitance switch can be connected to other circuits to control other machine and system functions.

In one aspect of this disclosure, the circuit system can be laminated or applied to a car window. The circuit system can be controlled by a microcontroller for directing certain LEDs to illuminate. The translucent circuit and LEDs can be arranged into various shapes to convey messages. For example, the translucent circuit and LEDs can be arranged on a car's sunroof to show a constellation of stars. In another example, the car's sunroof can be arranged in the shape of a graphic image such as a sports team logo, or a textual message.

Still other benefits and advantages of the invention will become apparent to those skilled in the art to which it pertains upon a reading and understanding of the following detailed specification.

### III. BRIEF DESCRIPTION OF THE FIGURES

The disclosed system can take physical form in certain parts and arrangement of parts, aspects of which will be described in detail in this specification and illustrated in the accompanying figures which form a part hereof.

FIG. 1 is a plan view diagram of a clear structure using the clear conductive ink and LEDs in accordance with an exemplary embodiment of the present invention.

FIGS. 2A and 2B are respective exploded and side view diagrams depicting elements of the flexible circuit structure with translucent conducive ink, opaque conductive ink, graphic ink, and LEDs as depicted in FIG. 1, in accordance with an exemplary embodiment of the present invention.

FIG. 3 is a plan view depicting an alternative arrangement of a clear structure using the translucent conducive ink, opaque conductive ink, graphic ink and a plurality of LEDs in accordance with an alternative exemplary embodiment of the present invention.

FIG. 4 is a schematic diagram depicting various operational components in accordance with an exemplary embodiment of the present invention.

### IV. DETAILED DESCRIPTION

Reference is now made with respect to the figures wherein the showings are for purposes of illustrating aspects of the disclosure only and not for purposes of limiting the same, and wherein like reference numerals are understood to refer to like components.

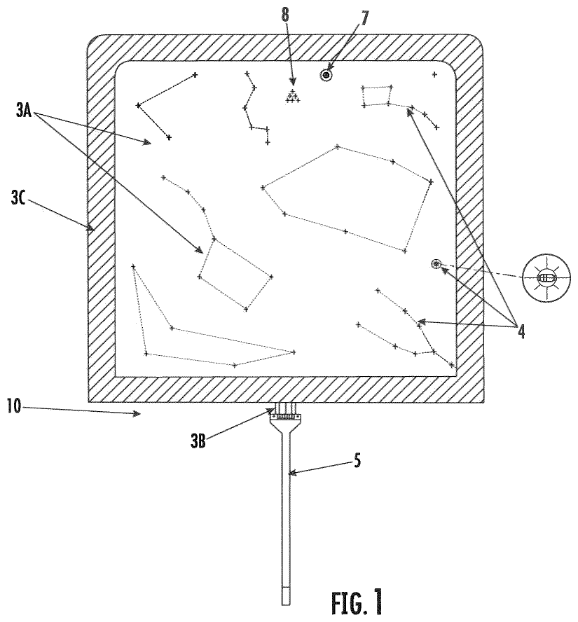

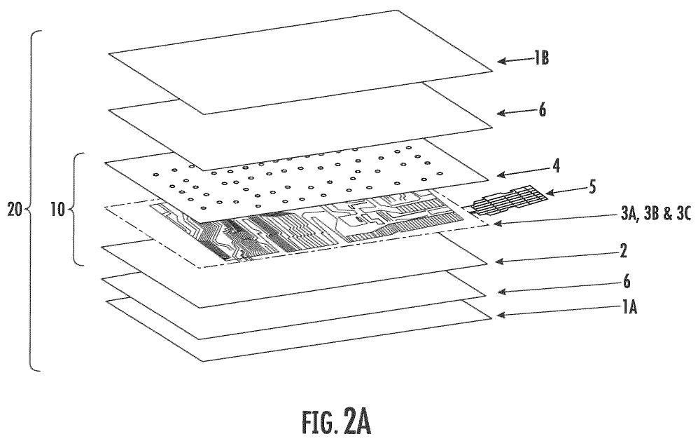

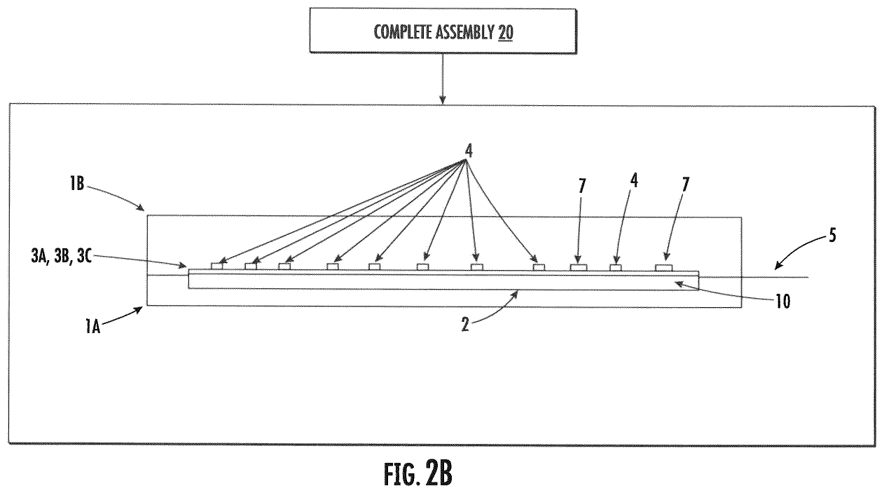

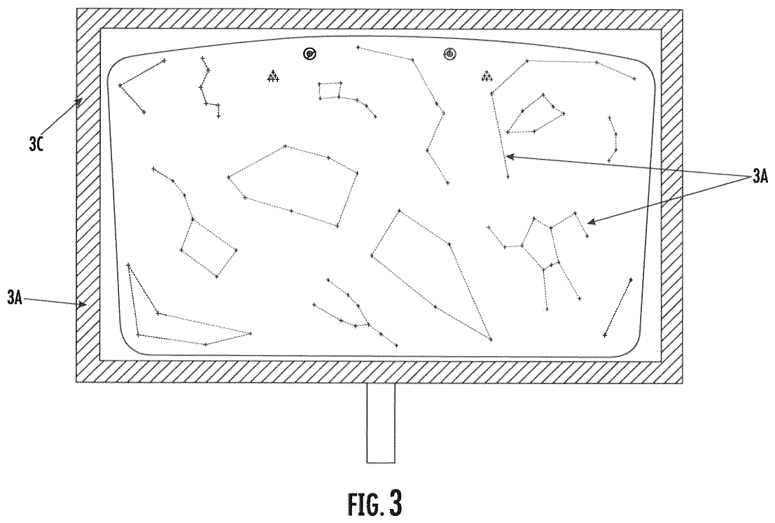

FIGS. 1, 2A, and 2B show a translucent circuit structure 10 in accordance with an embodiment of the present invention. The translucent circuit structure 10 can be laminated between or to a substrate 1A or 1B made of glass, plastic or another clear material to form a complete assembly of a clear structure 20. The clear structure 20 can be incorporated into a sunroof or a moonroof in an automobile or other vehicle, in which the glass can be safety glass as commonly used for vehicle windows. The clear structure 20 can include all or substantially all of the roof area of the automobile, or it can include a smaller portion of the roof area. The clear structure 20 can alternatively be incorporated into a vehicle window or other type of window. The clear structure 20 can be formed of one or more layers, as described in detail hereinbelow. In a preferred embodiment, the clear structure 20 can have the translucent circuit system 10 sandwiched between its layers.

With continuing reference to FIGS. 1, 2A and 2B, the translucent circuit system 10 can include an opaque conductive ink 3B trace layer and a translucent conducive ink layer 3A. The opaque conducive ink trace layer 3B can be a conductive silver paste ink or similar conductive material. The conductive opaque ink trace layer 3B can be arranged around the perimeter of the clear structure 20. The conductive opaque ink trace layer 3B or translucent conductive ink layer 3A can be bonded to a Flexible Printed Circuit (FPC) tail 5. The FPC tail 5 can be bonded to the opaque ink trace layer 3B or translucent conductive ink layer 3A by an Anisotropic Conductive Film (ACF) adhesive. It is to be appreciated that the FPC tail 5 defines an electrical connection for supplying power and control functions to the circuit system 10 and electronics within the clear structure 20.

With continuing reference to FIGS. 1, 2A and 2B, the translucent circuit system 10 can have the opaque ink trace layer 3B electrically connected to the translucent ink layer 3A. The translucent conductive ink layer 3A can be formed of either silver-carbon wires and/or carbon nanotube composite ink for conducting electrical current. The translucent conductive ink layer 3A can be formed of Chasm Agent 1 ink made by Chasm Advanced Material located in Boston, Massachusetts. The translucent conductive ink layer 3A can be translucent or partially opaque. The translucent circuit system 10 can include the opaque conductive ink trace layer 3B and a translucent conductive ink layer 3A as well as a nonconductive graphic ink layer 3C applied to a polymer such as polyethylene terephthalate (PET), polycarbonate (PC), or a different clear plastic. As shown in FIGS. 2A and 2B, the resulting polymer circuit layer 10 can be laminated or applied to a top layer 1B and a bottom layer 1A within which the other layers are sandwiched, using heat or adhesive or another such process. The polymer circuit and laminated FPC circuit can be heated, within reasonable engineering tolerances, to form within a polyvinyl butyral (PVB) layer 6 which can aid in the lamination process.

With continuing reference to FIGS. 1, 2A, and 2B, the translucent circuit system 10 can include a layer 4 with one or more Light Emitting Diodes (LEDs). The LED layer 4 can include LEDs from several LED manufacturers. The circuit system 10 can be arranged so that a plurality of LEDs 4 are arranged into different constellations. For example, shown in FIG. 1 is the Big Dipper and the Little Dipper formed onto a moonroof of a car. The translucent conductive ink layer 3A is configured to provide an electrical connection to the LED layer 4 and other electrical components described hereinbelow. The circuit system 10 can be sandwiched between the top and bottom layers 1A, 1B of the clear structure 20, where the clear structure 20 can be a component of a moonroof in an automobile.

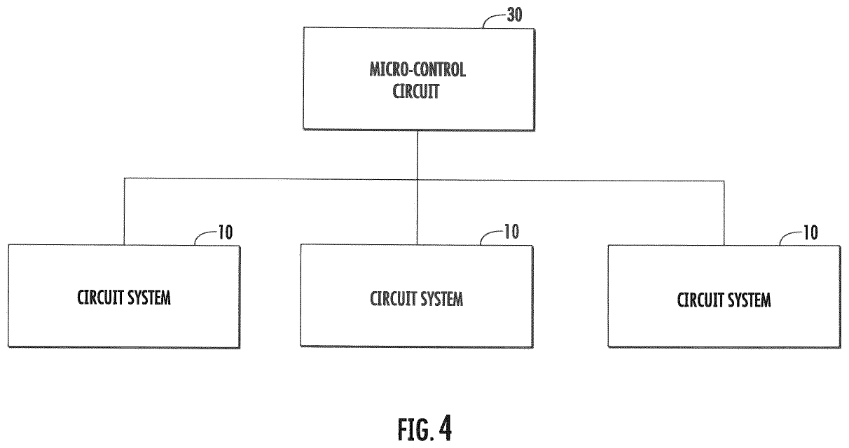

As shown in FIG. 4, the translucent circuit system 10 can be connected to a control circuit 30. The control circuit 30 can send and receive data between the translucent circuit system 10 and a host control system located in an automobile, or similar entity. Data and power inputs and outputs can be connected via the FPC tail 5. The circuit system 10 can be controlled by a microcontroller circuit 30 such that different constellations can be shown on the circuit structure 10 by directing a certain specific configuration of LEDs 4 to illuminate. The circuit system 10 can also be controlled to show a logo or display a textual message such as a vehicle's name. The clear structure 20 can alternatively include more than one circuit system 10, each controlled by the same microcontroller 30 or a different microcontroller provided by the host system. Another application would be to arrange one or more of the plurality of LEDs in the LED layer 4 in a cluster so it can function as a map or reading light 8. The LEDs 4 can be configured, and circuit system 10 can be controlled, so that any text-based message or image diagram can be displayed on clear structure 20.

With continuing reference to FIG. 1, the circuit system 10 can incorporate a capacitive button 7. The capacitive button 7 is configured within the transparent conductive ink layer 3A or opaque conductive ink layer 3B. The capacitive button 7 can switch when instigated by a finger of an operator. The capacitance button 7 can be used to send commands to the microcontroller 30 in order to control the circuit system 10. For example, the capacitance button 7 can control the brightness of one or more LED 4. This can be done by a series of repeated taps to add an incremental brightening, or to continuously hold down the button 7 to vary brightness. The circuit system 10 can alternatively include a plurality of capacitive buttons 7 to perform a respective plurality of control functions, alone or in combination with other buttons 7.

In an exemplary embodiment shown in the above figures, the circuit system 10 can be sized approximately 532 mm by 860 mm, or potentially larger. It can be populated with 98 LEDs 4 grouped into 18 different circuits. The LED 4 count can vary between 1 to 12 LEDs 4 per circuit with 24 traces in each circuit. The circuits can be laminated between one or two layers of polyvinyl butyral (PVB) 6 and then laminated between two layers of glass. Of course, it is to be appreciated that other suitable configurations and materials could alternately be employed without departing from the invention.

A method of manufacturing a clear structure 20 with a translucent circuit system 10 sandwiched between layers of a clear structure 20 includes the following. A translucent conductive ink layer 3A is deposited on a clear substrate 2. An opaque ink trace layer 3B is deposited onto the substrate 2. The translucent conductive ink layer 3A and the opaque ink trace layer 3B are applied in a substrate polymer 2 which is laminated between top and bottom polymer layers 1B, 1B. One or more LEDs 4 are optionally mounted to the polymer. An FCP tail 5 is connected to the opaque ink trace layer 3B or translucent conductive ink layer 3A with an ACF adhesive. The translucent circuit system 10 is laminated in between the layers 1A, 1B of the clear structure. Autoclaving the assembled clear structure 20 can be performed to fuse the layers.

Numerous embodiments have been described herein. It will be apparent to those skilled in the art that the above methods and apparatuses can incorporate changes and modifications without departing from the general scope of this invention. It is intended to include all such modifications and alterations in so far as they come within the scope of the appended claims or the equivalents thereof.

Having thus described the invention, it is now claimed:

1. A circuit system, comprising:
a clear substrate having a surface for application of a translucent conductive circuit thereupon;
a translucent conductive ink deposited upon the clear substrate for forming customizable and controllable arrangements to thereby form the translucent circuit;
a polymer encasement for embedding the clear substrate and clear circuit therein; and
an electrical connection from the circuit system to at least one electronic component.

2. The circuit system of claim 1, wherein the translucent conductive ink comprises an ink formulated of silver nano wires and carbon nanotubes.

3. The circuit system of claim 1, wherein the circuit system further comprises an opaque conductive ink trace comprising silver paste ink.

4. The circuit system of claim 1, wherein polymer encasement comprises at least one of polyethylene terephthalate (PET), Polycarbonate (PC), or a clear plastic.

5. The circuit system of claim 1, wherein the at least one electronic component comprises at least one light emitting diode (LED).

6. The circuit system of claim 5, wherein the at least one LED comprises a plurality of LEDs arranged in a pattern.

7. The circuit system of claim 6, wherein the plurality of LEDs are arranged in a pattern of one of a constellation, a graphic image or a textual message.

8. The circuit system of claim 1, wherein the at least one electronic component comprises at least one capacitive switch operating as a capacitive button for controlling an electronic device.

9. The circuit system of claim 1, wherein the clear substrate is a vehicle window.

10. A circuit system, comprising:
a clear substrate having a surface for forming a translucent circuit thereupon;
a translucent conductive ink deposited upon the clear substrate for forming customizable and controllable arrangements to thereby form the clear circuit;
a polymer encasement for embedding the clear substrate and translucent circuit therein; and
an electrical connection from the circuit system to a plurality of light emitting diodes (LEDs) arranged in a pattern.

11. A vehicle window, comprising:
a clear substrate having a surface for lamination of a transparent circuit thereupon;
a transparent conductive ink deposited upon the clear substrate for forming customizable and controllable arrangements to thereby form the clear circuit;
a polymer encasement for embedding the clear substrate and transparent circuit therein;
an electrical connection to a plurality of light emitting diodes (LEDs) embedded in the polymer encasement and arranged in a pattern; and
at least one capacitive switch operating as a capacitive button for controlling the plurality of LEDs.

12. The vehicle window of claim 11, wherein the vehicle window comprises an automobile sunroof.

13. The vehicle window of claim 11, further comprising a microcontroller actuated by the at least one capacitive switch for directing certain ones of the plurality of LEDs to illuminate.

14. The vehicle window of claim 13, wherein the microcontroller comprises programming to direct certain of the plurality of LEDs to illuminate to convey at least one message.
